(19) United States
(12) Patent Application Publication
(10) Pub. No.: US 2008/0303145 A1
(43) Pub. Date: Dec. 11, 2008

(54) Printed Circuit Board, Printed Circuit Board Manufacturing Method and Electronic Device

(75) Inventors: Minoru Takizawa, Sagamihara-shi (JP); Kuniyasu Hosoda, Hanno-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: Kabushiki Kaisha Toshiba, Tokyo (JP)

(21) Appl. No.: 12/128,558

(22) Filed: May 28, 2008

(30) Foreign Application Priority Data
May 30, 2007 (JP) 2007-143669

(51) Int. Cl. H01L 23/488; H01L 21/60

(52) U.S. Cl. 257/737; 438/106; 257/E21.509

(57) ABSTRACT

According to one embodiment, there is provided a printed circuit board which comprises a printed wiring board, a semiconductor package having a number of solder bonding members arranged on its back side and mounted on the printed wiring board by the solder bonding members being soldered to the wiring board, and reinforcing members which are formed of a reinforcing material having a solder flux function and locally reinforce the solder bonding members in a number of places on the semiconductor package mounting portion of the printed wiring board.

### CROSS-REFERENCE TO RELATED APPLICATIONS

This application is based upon and claims the benefit of priority from Japanese Patent Application No. 2007-143669, filed May 30, 2007, the entire contents of which are incorporated herein by reference.

### BACKGROUND

1. Field

One embodiment of the present invention relates to a printed circuit board having a semiconductor package mounted on it, the semiconductor package having a plurality of solder bonding members arranged on its back side.

2. Description of the Related Art

In electronic devices, such as personal computers, their casing houses as the main ingredient a circuit board which has a large-sized semiconductor package of some tens of millimeters square mounted on it. The semiconductor package constitutes a CPU and its associated peripheral circuitry, for example.

Such a circuit board as used in electronic devices, such as personal computers, requires means for protecting its semiconductor package mounted side from stress due to warp or deformation of the circuit board or externally applied shock or vibrations.

As means for protecting the soldered portions of a component mounting on a board from such stress, an electronic component mounting method is known which, in the case of a small-sized semiconductor chip of some millimeters square which is mounted on a board by a so-called face down boding technique, involves impregnating an under-fill agent between the board and the semiconductor chip to fill the gap therebetween, thereby fixing the semiconductor chip to the board (see JP-A No. 2005-026501, for example).

The under-fill-based reinforcing means has been widely applied to small-sized semiconductor chips of some millimeters square. When the reinforcing means is applied to a circuit board having a large-sized semiconductor package mounted on it, however, self-heat generation of the semiconductor package due to circuit operation causes the reinforcing material (under-fill agent) filled between the semiconductor chip and the board to repeat thermal expansion. As a result, there arises a problem that the soldered portions are subjected to excessive stress. In particular, in a circuit board on which a large-sized semiconductor package, such as a BGA or LGA, which has solder bonding members arranged on its back has been mounted, stress is concentrated on the corners of the rectangular package, leading to circuit break of the soldered portions. The more the reinforcing material is different in thermal expansion coefficient from the semiconductor package or the board, the more significant the problem becomes. In addition, there arises a problem of difficulty of rework because the entire side on which the large-sized semiconductor package is mounted is bonded to the board.

From the above-described points of view, the inventors have studied reinforcing means based on an adhesive but not under-fill for the corner portions of a large-sized semiconductor package (e.g., BSA package) which is used for the CPU or the like of a personal computer and susceptible to mechanical stress, such as drop impact. At present, a material and a process for simultaneously realizing the solder bonding of a semiconductor package and the hardening of a reinforcing material in reflow are under development. In the stage of development, there has arisen a new problem that the reinforcing material prevents solder from wet spreading at the time of solder bonding and consequently connection failures occur in the soldered portions.

According to one aspect of the present invention, there is provided a printed circuit board comprising: a printed wiring board; a semiconductor package having a number of solder bonding members arranged on its back side and mounted on the printed wiring board by the solder bonding members being soldered to the wiring board; and reinforcing members which are formed of a reinforcing material having a solder flux function and locally reinforce the solder bonding members in a number of places on the semiconductor package mounted side portion of the printed wiring board.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a side view of a printed circuit board according to a first embodiment of the present invention;

FIG. 2 is a plan view of the printed circuit board of FIG. 1;

FIG. 3 is a plan view of modified reinforcing members of the circuit board of FIG. 1;

FIG. 4 is a flowchart illustrating the manufacturing steps of the printed circuit board of FIG. 1;

FIG. 5 is a fragmentary side view, in one step of manufacture of the printed circuit board of FIG. 1;

FIG. 6 is a fragmentary side view, in a following step of manufacture of the printed circuit board of FIG. 5;

FIG. 7 is a fragmentary side view, in a following step of manufacture of the printed circuit board of FIG. 6;

FIG. 8 is a fragmentary side view, in a following step of manufacture of the printed circuit board of FIG. 7; and

FIG. 9 is a perspective view of an electronic device according to a second embodiment of the present invention.

### DETAILED DESCRIPTION

Various embodiments according to the invention will be described hereinafter with reference to the accompanying drawings.

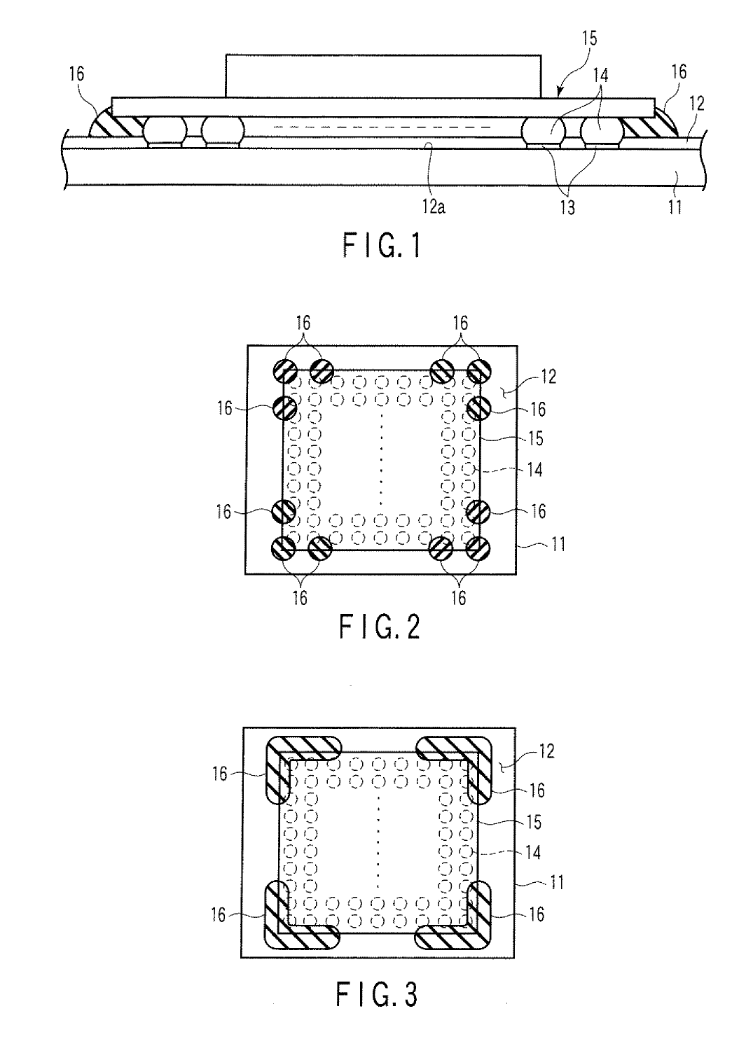

The structure of a printed circuit board according to a first embodiment of the present invention is illustrated in FIGS. 1 and 2, which are side and plan views, respectively, of the main part of the printed circuit board.

As shown in FIGS. 1 and 2, the printed circuit board includes a printed wiring board 11, a semiconductor package 15 which has a number of solder bonding members 14 arranged on its back side and is mounted on the printed circuit board 11 through solder bonding of the solder bonding members 14 through a solder resist film 12, and reinforcing members 16 which are formed of a material having a solder flux function and locally reinforce the solder bonding members 14 in a plurality of places on the semiconductor package mounted side of the printed wiring board 11 through the solder resist film 12. In this embodiment, the semiconductor package 15 is assumed to be a ball grid array (herein referred to as a BGA) package in which each of the solder bonding members 14 is a solder ball.

A wiring pattern formed surface of the printed wiring board 11 having the solder resist film 12 formed has a BGA component mounting area or portion 12a which is designed such that the BGA package 15 is to be mounted on it. The BGA component mounting portion 12a is formed with a number of solder bonding pads 13 each of which corresponds to a respective one of the solder bonding members 14 of the BGA package 15.

The BGA package 15 is mounted on the BGA component mounting portion l2a of the printed wiring board 11 by its solder bonding members 14 being soldered to the bonding pads 13 arranged on the BGA component mounting portion 12a.

In the reflow process to solder the BGA package 15, reinforcing members 16 which locally reinforce the solder bonding members 14 in a number of places are formed by thermosetting reinforcing material. The reinforcing members 16 are formed of a reinforcing material having a solder flux function for activating an oxidized surface of the solder. As a result, at the reflow heating time, solder of the BGA package 15 melts and the reinforcing material are softened while the solder flows into the soldering portions 14, thereby preventing the occurrence of bonding failures in the soldered portions. The reinforcing material to form the reinforcing members 16 will be described later.

With the BGA package 15 mounted on the BGA component mounting portion 12a, part of the solder bonding members (soldered portions) 14 are reinforced locally in the corner portions of the BGA component mounting portion by means of the reinforcing members 16 formed of a thermosetting resin. Here, in each of the corner portions of the BGA component mounting portion 12a, the solder bonding members 14 of the BGA package 15 are locally reinforced by means of three reinforcing members 16 in this embodiment. This reinforcement is effected by the reinforcing material adapted as an adhesive at a very small area at each of the corners of the BGA package 15 where small numbers of solder bonding members 14 are bonded onto the BGA component mounting portion 12a. Such local reinforcing members 16 allow the avoidance of the aforementioned problem caused by the under-fill material provided under the package 15 and the disadvantage that the solder bonding members 14 provided in the corner portions of the BGA package 15 break due to thermo-mechanical stress to result in bonding failures. Furthermore, the local reinforcing means makes rework easy.

With the first embodiment shown in FIGS. 1 and 2, the reinforcing members 16 are applied to each corner of the BGA component mounting portion 12a (each corner of the BGA package 15). At each corner of the mounting portion 12a, three reinforcing members 16 are applied. A first member 16 is placed at a very corner part and the remaining two members 16 are placed at two side parts near to the first member at the very corner part, thereby providing three reinforcing members 16 in each corner portion. This partial reinforcing arrangement is not restrictive. For example, as in the case of a second embodiment shown in FIG. 3, it is also possible to form a single reinforcing member 16 which reinforces a corner and portions of the two sides forming that corner in the shape of the letter L. Such a reinforcing structure will provide the same or the similar advantages as the arrangement shown in FIG. 2.

The reinforcing material to form the reinforcing member 16 is allowed to have the solder flux function by using a thermosetting resin, such as an epoxy-, acryl-, urethane- or phenol-based resin, which contains 5 to 15-percent organic acid. The resin, which softens when heated, has its viscosity to 20 to 80 Pa·s and containing a 5 to 15 percent thixotropy agent, such as humid silica, thereby preventing excessive flowing into the soldered portions. Thus, the reliability of the soldered portions can be increased. By using a thermosetting agent, such as isophthalic hydracid, which begins its thermosetting reaction at high temperatures of the order of about 220° C. for the thermosetting resin, even if use is made of an SnAg-based lead-free solder which has a melting point of about 220° C., the resin is allowed to harden at the same time the solder melts. That is, hardening of the resin does not precede melting of the solder. Furthermore, by containing a thermoplastic resin to the material forming the member 16, the rework characteristics after BGA package mounting can be further improved.

The use of such a reinforcing material and moreover simultaneous solder bonding and resin hardening allow good solder bonding and hardening of it to be realized.

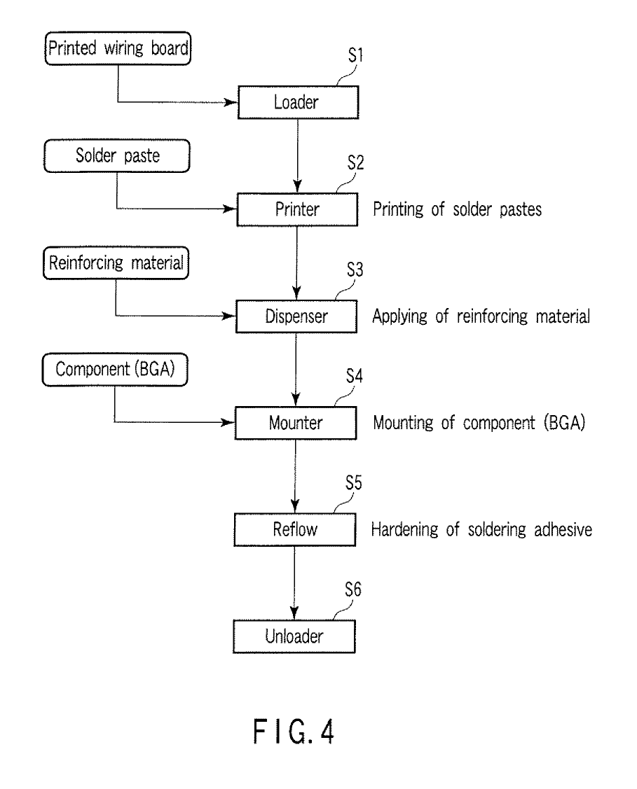

The process of manufacture of the printed circuit board using the aforementioned reinforcing material for the reinforcing members 16 to reinforce the solder bonding members (soldered portions) of the BGA package 15 is illustrated in FIG. 4.

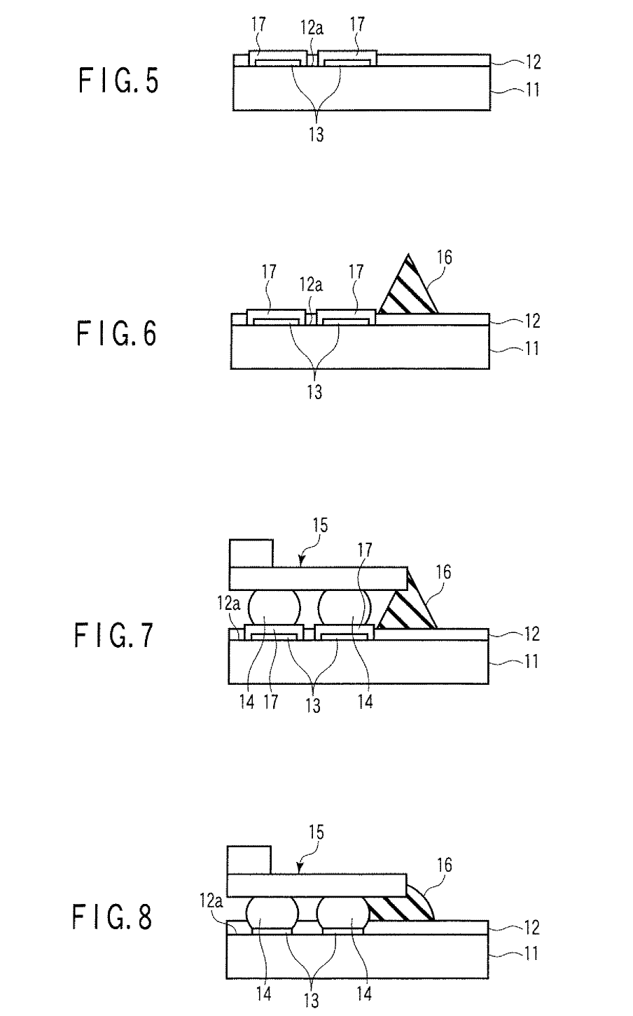

The manufacturing steps (S1 to S6) shown in FIG. 4 will be described with reference to FIGS. 5 to 8.

In step S1, a printed wiring board on which a component is to be mounted is supplied to a component line. Here, the supplied printed wiring board is the printed wiring board 11 which is formed, as shown in FIG. 1, with a number of bonding pads 13 on its BGA component mounting portion 12a pattern-designed so that the BGA package 15 is mounted on it, in correspondence to the solder bonding members 14 of the BGA package 15.

In step S2, a solder paste is printed on the to-be-soldered portions corresponding to the pads 13 of the printed wiring board 11 through the solder resist film 12 by using a printer. Here, as shown in FIG. 5, the solder paste 17 is printed on the bonding pads 13 arranged on the BGA component mounting portion 12a of the printed wiring board 11.

In step S3, a reinforcing material acting as adhesive is applied to the to-be-reinforced portions of the BGA component mounting portion 12a of the printed wiring board 11 via the solder resist film 12 with a dispenser. Here, as shown in FIG. 6, the reinforcing material to be formed as the member 16 having the solder flux function is applied locally to each corner portion of the BGA component mounting portion 12a (a corner and two places on two sides forming that corner and near to it: three places in total as described former) by a nozzle.

In step S4, a component 15 is mounted on the component mounting portion 12a of the printed wiring board 11. Here, as shown in FIG. 7, the BGA package 15 is mounted on the BGA component mounting portion 12a of the printed wiring board 11. At the time the component 15 is mounted, the reinforcing material 16 is interposed between the corner portions of the BGA component mounting portion 12a and the corner portions of the soldering surface of the BGA package 15.

In step S5, which is the solder reflow step, soldering of the component 15 to be mounted and hardening of the reinforcing material 16 (formation of the reinforcing members 16) are carried out at the same time. Here, as shown in FIG. 8, the solder bonding members 14 of the BGA package 15 are solder bonded to the bonding pads 13 by means of the printed solder paste 17 arranged on the BGA component mounting portion 12a of the printed wiring board 11 and the applied reinforcing members 16 are de-formed as the reinforcing members 16 in the corner portions of the mounting portion 12a.

In step S6, the reflow-processed printed wiring board 11 (printed circuit board) is handled by an un-loader and conveyed to the next step.

In the component mounting process described above, solder bonding of the package 15 and hardening of the resin or the reinforcing material are carried out at the same time and moreover the reinforcing material has the solder flux function, thus allowing good solder bonding and hardening of the reinforcing material to be achieved in a heat treatment (reflow) operation.

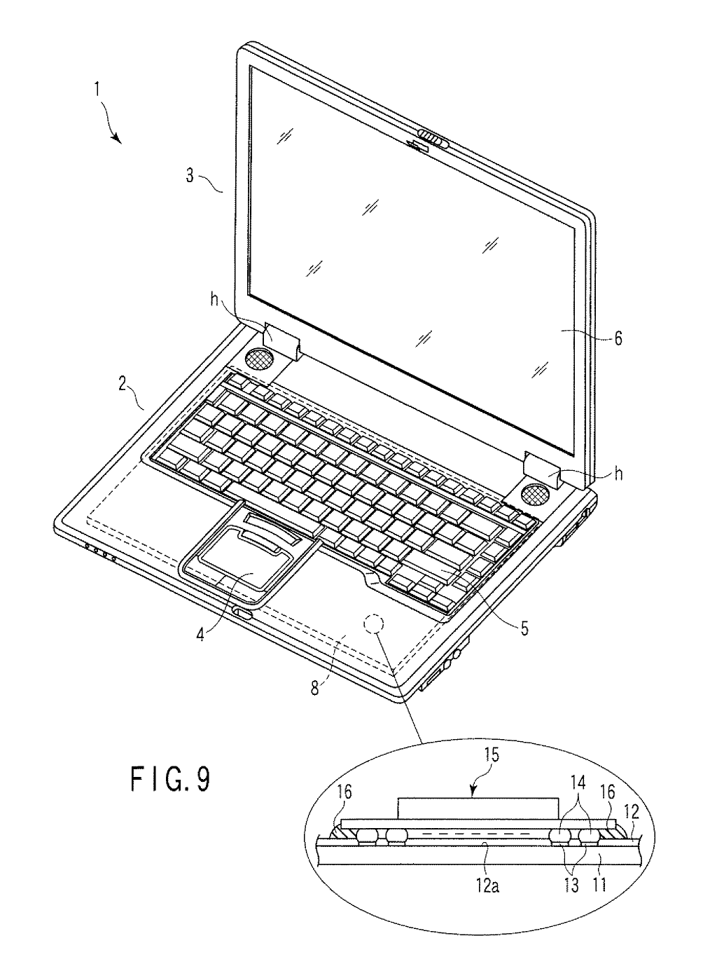

A second embodiment of the present invention is illustrated in FIG. 9.

The second embodiment is directed to an electronic device which uses the printed circuit board manufactured in accordance with the first embodiment. FIG. 9 shows an application of the printed circuit board according to the first embodiment to a small-sized electronic device, such as a portable computer.

In FIG. 9, a display casing 3 is mounted to the main body 2 of a portable computer 1 by a hinge mechanism h. The main body 2 is provided with a pointing device 4, a keyboard 5 and so on. A display device 6, such as an LCD, is housed in the display casing 3.

The main body 2 is provided with a circuit board (mother board) 8 which has a control circuit built in to control the operating unit including the pointing device 4 and the keyboard 5 and the display device 6. The circuit board 8 is implemented by using the printed circuit board of the first embodiment shown in FIGS. 1 and 2.

The circuit board 8 is composed of the printed wiring board 11, the BGA package 15 which has the solder bonding members 14 arranged on its back side and is mounted on the printed wiring board 11 by these solder bonding members 14 being soldered to the board 11, and the reinforcing members 16 which are formed of a reinforcing material having a solder flux function and locally reinforce part (e.g., the corner portions of the BGA package 15) of the solder bonding members 14 in a number of places (e.g., three places) on the BGA component mounting portion 12a of the printed wiring board 11.

The BGA package 15 mounted on the BGA component mounting portion 12a of the printed wiring board 11 has its solder bonding members (soldered portions) 14 locally reinforced by three reinforcing members 16 at three or four corner portions of the BGA component mounting portion. These local reinforcing members 16 can prevent the solder bonding members 14 in each of the corner portions of the BGA package 15 from being damaged when subjected to mechanical stress as when the user drops the electronic device by accident and leading to boding failures at the members 14. The BGA component 15 can therefore be expected to perform reliable and stable operations. Furthermore, the local reinforcing members 16 make rework of the printed circuit board easy.

While certain embodiments of the inventions have been described, these embodiments have been presented by way of example only, and are not intended to limit the scope of the inventions. Indeed, the novel methods and systems described herein may be embodied an a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed circuit board comprising:
a printed wiring board;
a semiconductor package having a number of solder bonding members arranged on its back side and mounted on the printed wiring board by the solder bonding members being soldered to the printed wiring board; and
reinforcing members which are formed of a reinforcing material having a solder flux function and locally reinforce the solder bonding members in a number of places on the semiconductor package mounting portion of the printed wiring board.

2. The printed circuit board according to claim 1, wherein the reinforcing members reinforce the corner portions of the semiconductor package.

3. The printed circuit board according to claim 1, wherein the reinforcing members reinforce each of the corner portions of the semiconductor package in three places, one being the corner, one being part on one of two sides forming the corner, and one being part on the other.

4. The printed circuit board according to claim 1, wherein the reinforcing material is a thermosetting resin which contains organic acid and has a viscosity of 20 to 80 Pa·s.

5. The printed circuit board according to claim 4, wherein the thermosetting resin is a resin selected from epoxy-, acryl-, urethane-, and phenol-based resins.

6. The printed circuit board according to claim 4, wherein the thermosetting resin further contains a thixotropy agent.

7. The printed circuit board according to claim 4, wherein the thermosetting resin further contains a thermoplastic resin.

8. A method of manufacturing a printed circuit board in which a semiconductor package having a number of solder bonding members arranged on its back side is mounted on a printed wiring board, comprising:
applying a reinforcing material having a solder flux function to a number of places on a side portion of the printed wiring board on which the semiconductor package is to be mounted;
mounting the semiconductor package on a semiconductor package mounting portion of the printed wiring board with the reinforcing material interposed there-between; and
performing the re-flow of the solder provided on the semiconductor package for mounting the same on the mounting portion of the printed wiring board and harden the reinforcing material to form reinforcing members which locally reinforce the solder bonding members of the semiconductor package in a number of places.

9. An electronic device comprising:
a main body; and
a circuit board contained in the main body,
wherein the circuit board comprises:
a printed wiring board;
a semiconductor package having a number of solder bonding members arranged on its back side and mounted on the printed wiring board by the solder bonding members being soldered to the wiring board; and
reinforcing members which are formed of a reinforcing material having a solder flux function and locally reinforce the solder bonding members in a number of places on the semiconductor package mounting portion of the printed wiring board.
